(19) United States
(12) Patent Application Publication
(10) Pub. No.: US 2009/0173377 A1
(43) Pub. Date: Jul. 9, 2009

(54) Solar Enclosure Apparatus and Method

(76) Inventors: Justin Meininger, Coral Gables, FL (US); Steven J. Miller, Tamarac, FL (US)

Correspondence Address: THE MILLER LAW OFFICES, PLC, 801 BRICKELL AVE, SUITE 900, MIAMI, FL, 33131, US

(21) Appl. No.: 11/969,926

(22) Filed: Jan. 7, 2008

(51) Int. Cl. H01L 31/048

(52) U.S. Cl. 136/251

(57) ABSTRACT

Solar energy has been used for generating electricity by using silicon based solar cells for years by mounting them on the outside surfaces of buildings. These cells have also been used for outdoor recreation, by mounting said silicon solar panels adjacent to a tent. To store the electrical energy produced by the silicon based cells, large, cumbersome battery systems were used. To provide needed working light inside of these solar powered building enclosures, the occupant needed separate light fixtures. This invention combines new light weight structurally flexible organic panels, said panels having three layers, said layers comprising an exterior solar photovoltaic layer, a middle layer of thin batteries and an interior layer of thin organic structurally flexible light emitting diode (“OLED”) film, said OLED's comprising the interior wall of said enclosure system. There is a microprocessor based circuit monitoring and management of the electrical energy produced, stored and used.

### CROSS REFERENCE TO RELATED APPLICATIONS

Not Applicable.

### STATEMENT REGARDING FEDERALLY SPONSORED RESEARCH OR DEVELOPMENT

Not Applicable

### DESCRIPTION OF ATTACHED APPENDIX

Not Applicable

### BACKGROUND OF THE INVENTION

1. Field of the Invention

The present invention relates to an solar energy powered habitat enclosure system, capable of being used as a human and/or animal portable or permanent habitat, said system comprising an assembly of individual layered panels, wherein the exterior and interior layer within said panels, are made substantially of structurally flexible organic based materials, including, the exterior layer being for photovoltaic solar energy collection, the middle layer for resultant electrical energy battery storage, the interior layer for light emitting diode illumination, and a microprocessor based integrated circuit to monitor and manage said enclosure system.

2. Description of the Prior Art

Solar energy has been used for generating electricity through the use of silicon based photovoltaic solar cells for many years by mounting them on, and having them supported by, the roof and/or wall structural materials of residential and commercial building structures. Likewise, the use of these silicon photovoltaic cells have been used for outdoor recreational use, by mounting one or more of said panels next to, or over the top of a tent. In the prior art, to store the electrical energy produced by the silicon based collectors, large, cumbersome battery systems were used. Then traditional electrical loads, like lamps, etc. were plugged into electrical outlets powered off of those batteries. The problem that exists in the prior art, is that the silicon solar panels needed to be mounted on, and structurally supported by existing building structure; i.e. roofs and walls. Also, the traditional batteries, were heavy and therefore not portable, and they also had large space requirements. Finally, to provide needed working light inside of these solar powered building enclosures, the occupant need to have additional separate and heavy light fixtures. The current invention solves the problem of the heavy structure and weight that makes solar energy use cumbersome in parmanent structures and extremely difficult on portable structures, by combining new light weight and structurally flexible organic panels, as further described herein, said panels having three layers, said layers comprising an exterior solar photovoltaic layer, a light weight and structurally flexible middle layer of thin batteries, and an interior layer of thin organic structurally flexible light emitting diode (“OLED”) film, said OLED's comprising the actual interior wall of said habitat enclosure system. A microprocessor based integrated circuit energy management system providing monitoring, safe and proper functioning of the electrical energy produced, stored and distributed for the individual multi-layered panels and/or the entire panel assembled habitat enclosure system.

In U.S. Patent Publication No. US 2006/0102217 (“Hsiang”), the invention discloses a portable tent structure, with solar panels placed “on” or “over the tent”, and also the solar panels placed “on” a “side” of the tent. The invention, while disclosing batteries for energy storage, does not disclose how a person would transport traditional heavy batteries to a remote camping location, and the invention does not disclose the battreies being part of the very tent enclosure. Also, the invention discloses a simple “switching device”, and not a microprocessor based energy management system. In U.S. Pat. No. 5,542,989 (“Ichikawa”), the invention discloses a solar house, again with the solar panels being mounted “on” the roof, and the “batteries” being attached to “mounts” affixed to existing roof structural “members”. The present invention does not require any structural roof or wall/side members to be mounted “on”, but rather is comprised of structurally flexible materials that are, in fact, also the actual solar panel itself, the batteries themselves, and the interior lighting itself. This solves the problem by having a lightweight, efficient, quickly assembled self sufficient solar powered habitat enclosure system.

### BRIEF SUMMARY OF THE INVENTION

The objective of the present invention is to provide a layered panel and an assembled habitat enclosure system comprised of an assembly of said panels with solar energy panels to absorb solar energy and transform it into electric energy via a solar energy to electric energy switching device, thereby providing a power supply. For achieving the above objective, the invention combines new light weight and structurally flexible organic panels, more particularly described below, said panels having three layers, said layers comprising an exterior solar photovoltaic layer, a light weight and structurally flexible middle layer of thin batteries, and an interior layer of thin organic structurally flexible light emitting diode (“OLED”) film, said OLED's comprising the actual interior wall of said habitat enclosure system. A microprocessor based integrated circuit energy management system providing monitoring, safe and proper functioning of the electrical energy produced, stored and distributed for the individual multi-layered panels and/or the entire panel assembled habitat enclosure system.

On the exterior layer of the layered panels, this invention uses new lightweight, structurally flexible, solar cells made of organic materials; i.e. cells based on polymers with carbon bonds. Currently, organic semi-conductors include not only polymers [molecular mass greater than 10,000 AMU (atomic mass units)], but also small molecules (molecular mass less than a few thousand AMU), and dendrimers (molecular masses between the polymers and small molecules). Organic solar cells work differently from conventional inorganic semiconductor solar cells. Light absorbed by an inorganic semiconductors produce free charge carriers—electrons and holes—that are transported separately through the semiconductor material. In an organic solar cell, however, light absorption produces excitons, electron-hole pairs that are bound together and hence not free to move separately. To generate free charge carriers, the excitons must be dissociated. This can happen in the presence of high electric fields, at a defect site in the material, or usually, at the interface between two materials that have a sufficient mismatch in their energy levels. Thus, an organic solar cell can be made with the following layered structure: positive electrode/electron donor/electron acceptor/negative electrode. An exciton created in either the electron donor or electron acceptor layer can diffuse to the interface between the two, leading to electron transfer from the donor material to the acceptor, or hole transfer from the acceptor to the donor. The negatively charged electron and the positively charged hole is then transported to the appropriate electrode. Organic materials are diverse and versatile, offering endless possibilities for improving a wide range of properties such charge generation, separation, molecular mass, wettability between organic molecules and inorganic material, the ability to harvest light efficiently in different parts of the solar spectrum, especially the infrared, molecular energy levels, rigidity, and molecule-to-molecule interactions. Different organic molecules can be combined with one another, or with inorganic materials in many unique formulations. One major advantage of organic solar panels is the low cost involved in manufacture. Organic molecules are cheap to make, they can have very high light absorbing capacity so that films as thin as several hundred nanometres would be sufficient for the purpose. Organic materials are compatible with plastic and other flexible substrates; and devices can therefore be fabricated with low-cost, high throughput printing techniques that consume less energy and require less capital investment than silicon-based devices and other thin-film technologies. Consequently, organic solar cells do not need to have conversion efficiencies as high as thin-film inorganic solar cells to become competitive in the market. Another advantage of these cells is that they are good for high latitudes. They do not have the reflectivity of inorganic materials such as silicon, which allows them to have greater conversion efficiency when the sun is at high angles relative to the cell.

The middle layer of the current invention is comprised of structurally flexible batteries. Said batteries may be, though are not required to be, polymer based batteries which have a different design from the older lithium-ion cells. Unlike lithium-ion cylindrical or prismatic cells, which have a rigid metal case, polymer cells have a flexible, foil-type (polymer laminate) case, but they still contain organic solvent. The main difference between commercial polymer and lithium-ion cells is that in the latter the rigid case presses the electrodes and the separator onto each other, whereas in polymer cells this external pressure is not required because the electrode sheets and the separator sheets are laminated onto each other. Since no metal battery cell casing is needed, the battery can be lighter and it can be specifically shaped to fit the device it will power. Because of the denser packaging without intercell spacing between cylindrical cells and the lack of metal casing, the energy density of Li-poly batteries is over 20% higher than that of a classical Li-ion battery and approximately three times better than nickel-cadmium (NiCad) and nickel metal hydride (NiMH) batteries. A compelling advantage of Li-poly cells is that manufacturers can shape the battery almost however they please. The interior layer of the current invention is comprised of light emission from organic materials not very common in everyday life. However, some living creatures, such as fireflies and many sea creatures, emit light with amazingly high efficiencies. The biological process is called electrophosphorescence and has been exploited in organic light emitting diodes (“OLED's”). These devices consist of one or more polymer films between two transparent electrodes. Application of a voltage across the electrodes causes light to be emitted from the OLED. OLED panels make efficient solid-state lighting and they can produce white light much closer to natural light than that of fluorescent tubes, without the annoying flicker. Production is much simpler than for conventional lighting displays. OLEDs can be printed like newspapers, rather than computer chips. For OLEDs, the charges forming the electric current that drives the device move around the device after injection from the electrodes; they pair up with charges of the opposite sign to form the bound pairs known as excitons that diffuse around the device before emitting light.

### BRIEF DESCRIPTION OF THE DRAWINGS

The drawings constitute a part of this specification and include exemplary embodiments to the invention, which may be embodied in various forms. It is to be understood that in some instances various aspects of the invention may be shown exaggerated or enlarged to facilitate an understanding of the invention.

In the drawings:

FIG. 1 is a perspective view of the exterior of one embodiment in accordance with the invention;

FIG. 2 is a perspective view of the exterior of a second embodiment in accordance with the invention;

FIG. 3 is an elevation view of a cross-section of a layered panel system in accordance with the invention;

FIG. 4 is a functional block diagram of the microprocessor based integrated circuit in accordance with the invention.

### DETAILED DESCRIPTION OF THE EMBODIMENTS

Detailed descriptions of the preferred embodiments are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

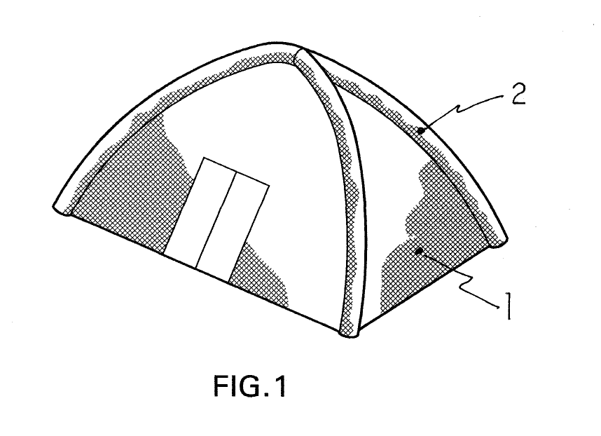

FIG. 1 is perspective view of one geometric confguration and embodiment for the invention. It comprises an assembled habitat enclosure system of layered panels, said panels combining new light weight and structurally flexible organic panels, said panels having three layers, said layers comprising an exterior solar photovoltaic layer, a light weight and structurally flexible middle layer of thin batteries, and an interior layer of thin organic structurally flexible light emitting diode (“OLED”) film, said OLED's comprising the actual interior wall of said habitat enclosure system. Said mutli-layered structurally flexible panel may optionally be enclosed, on its perimeter with a structurally flexible individual panel frame. A microprocessor based integrated circuit energy management system providing monitoring, safe and proper functioning of the electrical energy produced, stored and distributed for the individual multi-layered panels and/or the entire panel assembled habitat enclosure system. In this embodiment, said layered panels are shaped in circular sector (or “pie-like”) shapes 1, and each of said circular sector shape layered panels being assembled as a unit. In this embodiment, circular sector shaped panels 1 are connected to one another via a structurally supportive, but structurally flexible framing system comprised of individual frame elements 2, that may be tubular shaped, or other appropriate geometric shape, and said elements may be made from organic based materials, or other structurally flexible and structurally supportive material. Said frame elements 2, may also be made of an inflatable material, wherein said inflatable material when deflated allows for easy folding and packing of said layered panels for transport; and when inflated, said frame elements 2, are structurally flexible and structurally supportive. Structurally supportive means that the frame elements 2, when assembled, have sufficient material strength to allow, and maintain, the complete assembly of the habitat enclosure system for use by individuals or animals. Structurally flexible, means that the frame elements 2, can bend suffiently, to allow for the interconnection of the individual circular sector shaped layered panels 1, into the assembled “pyramid-like” shape illustrated by FIG. 1.

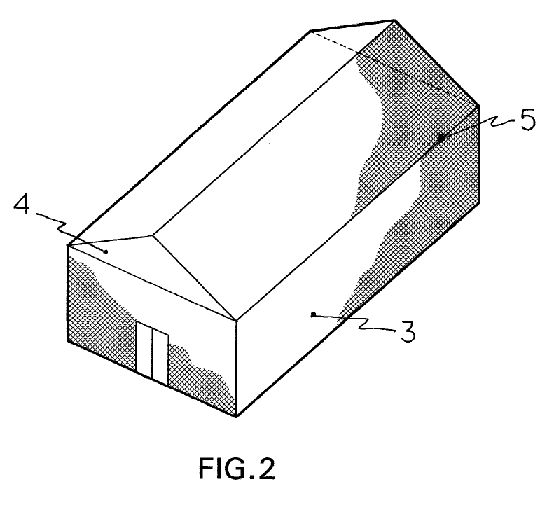

FIG. 2 is perspective view of one geometric confguration and embodiment for the invention. It comprises an assembled habitat enclosure system of layered panels, said panels combining new light weight and structurally flexible organic panels, said panels having three layers, said layers comprising an exterior solar photovoltaic layer, a light weight and structurally flexible middle layer of thin batteries, and an interior layer of thin organic structurally flexible light emitting diode (“OLED”) film, said OLED's comprising the actual interior wall of said habitat enclosure system. A microprocessor based integrated circuit energy management system providing monitoring, safe and proper functioning of the electrical energy produced, stored and distributed for the individual multi-layered panels and/or the entire panel assembled habitat enclosure system. In this embodiment, said layered panels are shaped in rectangular shapes 3 and/or triangular shapes 4, and each of said rectangular and/or triangular shapes' layered panels being assembled as a unit. In this embodiment, these rectangular 3 and/or triangular panels 4 are connected to one another via a structurally supportive, but structurally flexible framing system comprised of individual frame elements 5, that may be tubular shaped, or other appropriate geometric shape, and said elements may be made from organic based materials, or other structurally flexible and structurally supportive material. Said frame elements 5, may also be made of an inflatable material, wherein said inflatable material when deflated allows for easy folding and packing of said layered panels for transport; and when inflated, said frame elements 5, are structurally flexible and structurally supportive. Structurally supportive means that the frame elements 5, when assembled, have sufficient material strength to allow, and maintain, the complete assembly of the habitat enclosure system for use by individuals or animals. Structurally flexible, means that the frame elements 5, can bend suffiently, to allow for the interconnection of the individual circular sector shaped layered panels 1, into the assembled “barn-like” shape illustrated by FIG. 2.

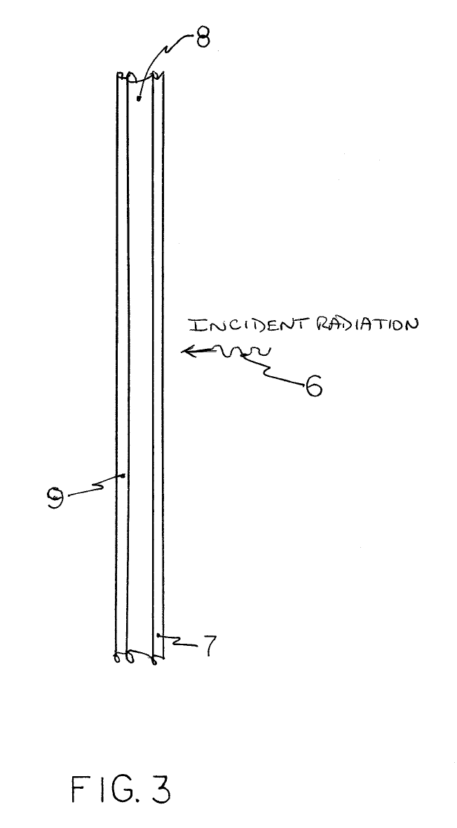

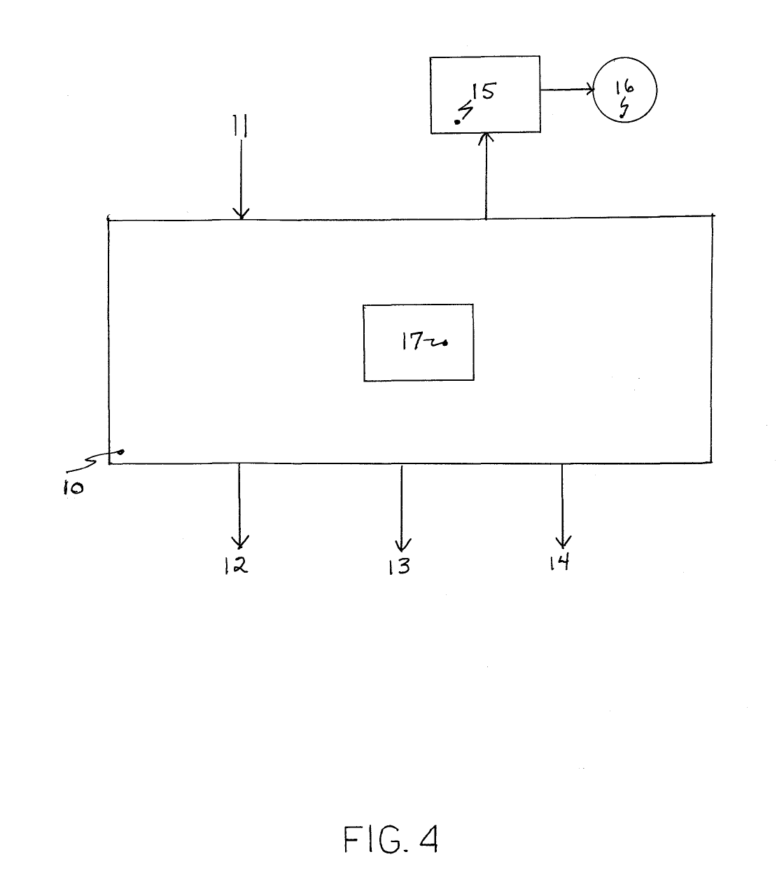

FIG. 3 is an elevation view of a cross-section of a layered panel system in accordance with the invention, wherein it is illustrated, that the exterior layer 7 of the three layered panel receives the photons 6 of any incident radiation from any radiation source, including, but not limited to, direct solar radiation and/or reflected solar radiation. On this exterior layer 6 of the layered panels, this invention uses new lightweight, structurally flexible, solar cells made of organic materials; i.e. cells based on polymers with carbon bonds. Currently, organic semi-conductors include not only polymers [molecular mass greater than 10,000 AMU (atomic mass units)], but also small molecules (molecular mass less than a few thousand AMU), and dendrimers (molecular masses between the polymers and small molecules). Organic solar cells work differently from conventional inorganic semiconductor solar cells. Light absorbed by an inorganic semiconductors produce free charge carriers—electrons and holes—that are transported separately through the semiconductor material. In an organic solar cell, however, light absorption produces excitons, electron-hole pairs that are bound together and hence not free to move separately. To generate free charge carriers, the excitons must be dissociated. This can happen in the presence of high electric fields, at a defect site in the material, or usually, at the interface between two materials that have a sufficient mismatch in their energy levels. Thus, an organic solar cell can be made with the following layered structure: positive electrode/electron donor/electron acceptor/negative electrode. An exciton created in either the electron donor or electron acceptor layer can diffuse to the interface between the two, leading to electron transfer from the donor material to the acceptor, or hole transfer from the acceptor to the donor. The negatively charged electron and the positively charged hole is then transported to the appropriate electrode to produce a electrical energy across said electrodes of said individual organic solar cell. Said electrical energy is monitored and then directed via the microprocessor based electrical power management integrated circuit (FIG. 4), to the structurally flexible batteries located in the middle layer 8, and/or the OLED's located in the interior layer 9 of said panel and/or to any user selected optional loads (including, but not limited to, televisions, radios, audio equipment, etc.). The interior layer 9 of the current invention is comprised of light emission from organic materials. Electrophosphorescence has been exploited in organic light emitting diodes (“OLED's”). These devices consist of one or more polymer films between two transparent electrodes. Application of a voltage across the electrodes causes light to be emitted from the OLED. OLED panels make efficient solid-state lighting that produce white light much closer to natural light than that of fluorescent tubes. For OLEDs, the charges forming the electric current that drives the device move around the device after injection from the electrodes; they pair up with charges of the opposite sign to form the bound pairs known as excitons that diffuse around the device before emitting light.

FIG. 4 is a functional block diagram of the microprocessor based integrated circuit that monitors and manages the proper and safe production of the electrical energy in the exterior layer 7 of said multi-layered panels (FIG. 3), the proper and safe storage of the electrical energy in structurally flexible batteries located in the middle layer 8 of said panels (FIG. 3), and the proper and safe distribution of the electrical energy used by the OLED's located in the interior layer 9 of said panels (FIG. 3), and other optional user selected electrical loads. Reviewing FIG. 4, the microprocessor based electrical energy management system is comprised of an integrated circuit 10, said integrated circuit being comprised of the inputs from the output electrical energy 11 produced by each of the layered panels' exterior layers, distributed electrical energy output 12 to each of the structurally flexible batteries located in the middle layer to maintain their proper charge, distributed electrical energy output to the OLED's 13 located in the interior layer as well as to other optional user selected electrical loads 14, an optional visual monitoring display 15 with optional audible alarms 16 for improper operation, a microprocessor chip 17 programmed with non-volatile memory and/or battery back-up to properly manage the safe aforementioned habitat enclosure system electrical energy collection, storage and distribution.

While the invention has been described in connection with the above described embodiments, it is not intended to limit the scope of the invention to the particular form set forth, but on the contrary, it is intended to cover such alternatives, modifications, and equivalents as may be included within the spirit and scope of the invention as defined by the appended claims.

What is claimed is:

1. A solar energy electrical generating habitat enclosure system panel apparatus comprising:
An exterior layer exposed to solar radiation, said layer being comprised of structurally flexible organic based materials and having photovoltaic properties to produce electrical energy from any natural or artificial light source;
An interior layer exposed to the interior living area of said habitat, said interior layer being comprised of structurally flexible organic based light emitting materials wherein any part of or all of said interior layer surface is capable of providing light to the interior of said habitat;
A middle layer located between said exterior layer and said interior layer, said middle layer comprising structurally flexible battery elements to store and distribute the electrical energy produced by said exterior layer;
A microprocessor based electrical energy management integrated circuit comprising elements for regulating the charging, storage and distribution of electrical energy for the entire habitat enclosure panel.

2. The panel of claim 1 wherein said interior layer is comprised completely of structurally flexible organic light emiting diode material.

3. The apparatus of claim 1 wherein said middle layer's battery elements are made of structurally flexible organic based materials.

4. The apparatus of claim 1 further comprising a portable framing system assembly, fabricated of structurally flexible materials to which said panels, when assembled with said frame, comprise a complete assembled habitat enclosure system for humans or animals.

5. The apparatus of claim 1 further comprising a permanent framing system assembly, fabricated of structurally flexible materials to which said panels, when assembled with said frame, comprise a complete assembled habitat enclosure system for humans or animals.

6. The apparatus of claim 1 further comprising a portable framing system assembly, fabricated of structurally flexible inflatable materials to which said panels, when assembled with said frame, comprise a complete assembled habitat enclosure system for humans or animals.

7. The apparatus of claim 1 wherein said microprocessor based electrical energy management integrated circuit has a system parameters visual display.

8. The apparatus of claim 1 wherein said microprocessor based electrical energy management integrated circuit has an improper system parameters audible alarm.

9. The apparatus of claim 1 wherein each individual panel of said apparatus is enclosed on its perimeter by a structurally flexible material.

10. A method for assembling a solar powered habitat enclosure system panel apparatus comprising:
An exterior layer exposed to solar radiation, said layer being comprised of structurally flexible organic based materials and having photovoltaic properties to produce electrical energy from any natural or artificial light source;
An interior layer exposed to the interior living area of said habitat, said interior layer being comprised of structurally flexible organic based light emitting materials wherein any part of or all of said interior layer surface is capable of providing light to the interior of said habitat;
A middle layer located between said exterior layer and said interior layer, said middle layer comprising structurally flexible battery elements to store and distribute the electrical energy produced by said exterior layer;
A microprocessor based electrical energy management integrated circuit comprising elements for regulating the charging, storage and distribution of electrical energy for the entire habitat enclosure panel.

11. The method of claim 10 wherein said interior layer is comprised completely of structurally flexible organic light emiting diode material.

12. The method of claim 10 wherein said middle layer's battery elements are made of structurally flexible organic based materials.

13. The method of claim 10 further comprising a portable framing system assembly, fabricated of structurally flexible materials to which said panels, when assembled with said frame, comprise a complete assembled habitat enclosure system for humans or animals.

14. The method of claim 10 further comprising a permanent framing system assembly, fabricated of structurally flexible materials to which said panels, when assembled with said frame, comprise a complete assembled habitat enclosure system for humans or animals.

15. The method of claim 10 further comprising a portable framing system assembly, fabricated of structurally flexible inflatable materials to which said panels, when assembled with said frame, comprise a complete assembled habitat enclosure system for humans or animals.

16. The method of claim 10 wherein said microprocessor based electrical energy management integrated circuit has a system parameters visual display.

17. The method of claim 10 wherein said microprocessor based electrical energy management integrated circuit has an improper system parameters audible alarm.

18. The method of claim 10 wherein each individual panel of said apparatus is enclosed on its perimeter by a structurally flexible material.
